(19) United States
(12) Patent Application Publication
(10) Pub. No.: US 2019/0296063 A1
(43) Pub. Date: Sep. 26, 2019

(54) FOCUS DETECTION APPARATUS AND IMAGE CAPTURING APPARATUS

(71) Applicant: CANON KABUSHIKI KAISHA, Tokyo (JP)

(72) Inventor: Takashi Ichimiya, Yokohama-shi (JP)

(21) Appl. No.: 16/363,279

(22) Filed: Mar. 25, 2019

(30) Foreign Application Priority Data
Mar. 26, 2018 (JP) 2018-058657

(51) Int. Cl. H01L 27/146; H04N 5/232; H04N 5/341

(52) U.S. Cl. CPC H01L 27/14605; H04N 5/341; H04N 5/23212

(57) ABSTRACT

A focus detection apparatus comprises: an image sensor having a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, and a scanning unit that selects rows of the pixel area from which signals are read out, wherein the first light receiving areas and the second light receiving areas are arranged so as not to be simultaneously included in the rows selected by the scanning unit.

### BACKGROUND OF THE INVENTION

### Field of the Invention

The present invention relates to a focus detection apparatus and an image capturing apparatus.

### Description of the Related Art

Conventionally, a phase difference detection type image capturing apparatus is known. In the phase difference detection method, light from a subject is divided into two images using two convex lenses arranged side by side, and a focus state is detected from a phase difference between a pair of image signals corresponding to the respective images.

Japanese Patent Laid-Open No. 10-104502 discloses a configuration in which an area sensor capable of detecting correlation in a longitudinal direction and an area sensor capable of detecting correlation in a lateral direction are arranged on one chip and the readout direction is changed for each area sensor.

However, in the conventional technique disclosed in the above-mentioned Japanese Patent Laid-Open No. 10-104502, since the readout direction is changed for each image forming area, the circuit scale between the area sensors becomes necessarily large. Therefore, the sensor layout is restricted, and the size of the image capturing device itself as well as the size of the sensor increases.

### SUMMARY OF THE INVENTION

The present invention has been made in consideration of the above situation, and shortens the time required for focus detection processing while suppressing the circuit scale of the area sensor used as the focus detection sensor.

According to the present invention, provided is a focus detection apparatus comprising: an image sensor having a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, and a scanning unit that selects rows of the pixel area from which signals are read out, wherein the first light receiving areas and the second light receiving areas are arranged so as not to be simultaneously included in the rows selected by the scanning unit.

Further, according to the present invention, provided is a focus detection apparatus comprising: a dividing unit that divides incoming light beams that enter via an imaging optical system into a plurality of different directions; an image sensor having a pixel region, having a plurality of pixels, which includes a plurality of pairs of light receiving areas that receive the light beams divided by the dividing unit, and a scanning unit that selects rows of the pixel area from which signals are read out; and a focus detection unit that detects a focus state based on phase differences between a plurality of pairs of signals read out from the plurality of pairs of light receiving areas, respectively, wherein the dividing unit divides the light beams so that the plurality of pairs of light receiving areas whose detection directions of the phase difference are different are not simultaneously included in the rows selected by the scanning unit.

Furthermore, according to the present invention, provided is a focus detection apparatus comprising: an image sensor having a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, a first light-shielded region and a second light-shielded region provided along periphery of the pixel region in the first direction and in the second direction, respectively, and a scanning unit that selects rows of the pixel area from which signals are read out, wherein the scanning unit selects the rows so as to read out signals from the first light-shielded region in order to correct a pair of first signals read out from the pair of first light receiving areas and to read out signals from the second light-shielded region in order to correct a pair of second signals read out from the pair of second light receiving areas.

Further, according to the present invention, provided is an image capturing apparatus comprising: an image sensing device that performs photoelectric conversion on light beams incoming via an imaging optical system and outputs an image signal; the focus detection apparatus comprising an image sensor having a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, and a scanning unit that selects rows of the pixel area from which signals are read out; and a controller that controls the imaging optical system based on a focus state detected by the focus detection apparatus, wherein the first light receiving areas and the second light receiving areas are arranged so as not to be simultaneously included in the rows selected by the scanning unit.

Further, according to the present invention, provided is an image capturing apparatus comprising: an image sensor that performs photoelectric conversion on light beams incoming via an imaging optical system and outputs an image signal; the focus detection apparatus comprising a dividing unit that divides incoming light beams that enter via an imaging optical system into a plurality of different directions; an image sensor having a pixel region, having a plurality of pixels, which includes a plurality of pairs of light receiving areas that receive the light beams divided by the dividing unit, and a scanning unit that selects rows of the pixel area from which signals are read out; and a focus detection unit that detects a focus state based on phase differences between a plurality of pairs of signals read out from the plurality of pairs of light receiving areas, respectively; and a controller that controls the imaging optical system based on a focus state detected by the focus detection apparatus, wherein the dividing unit divides the light beams so that the plurality of pairs of light receiving areas whose detection directions of the phase difference are different are not simultaneously included in the rows selected by the scanning unit.

Further, according to the present invention, provided is an image capturing apparatus comprising: an image sensor that performs photoelectric conversion on light beams incoming via an imaging optical system and outputs an image signal; the focus detection apparatus comprising an image sensor having a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, a first light-shielded region and a second light-shielded region provided along periphery of the pixel region in the first direction and in the second direction, respectively, and a scanning unit that selects rows of the pixel area from which signals are read out; and a controller that controls the imaging optical system based on a focus state detected by the focus detection apparatus, wherein the scanning unit selects the rows so as to read out signals from the first light-shielded region in order to correct a pair of first signals read out from the pair of first light receiving areas and to read out signals from the second light-shielded region in order to correct a pair of second signals read out from the pair of second light receiving areas.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIG. 1 is a schematic sectional view of a camera as an image capturing apparatus according to a first embodiment of the present invention;

FIG. 2 is a perspective view schematically showing a configuration of a focus detection system according to the first embodiment;

FIG. 3 is a circuit diagram of a focus detection sensor according to the first embodiment;

FIG. 4 is a timing chart showing drive timing of the focus detection sensor according to the first embodiment;

FIG. 5 is a diagram showing a layout of the focus detection sensor according to the first embodiment;

FIGS. 6A and 6B are views for explaining a readout row and a readout time of the focus detection sensor according to the first embodiment;

FIG. 7 is a view showing an AF area in a viewfinder screen according to the first embodiment;

FIG. 8 is a flowchart showing a procedure of imaging control processing in the image capturing apparatus according to the first embodiment;

FIG. 9 is a flowchart showing a procedure of AF processing according to the first embodiment;

FIG. 10 is a diagram showing a layout of a focus detection sensor according to a second embodiment;

FIG. 11 is a diagram showing a relationship between AF areas in a viewfinder screen according to the second embodiment; and

FIG. 12 is a flowchart showing a procedure of AF processing according to the second embodiment.

### DESCRIPTION OF THE EMBODIMENTS

Exemplary embodiments of the present invention will be described in detail in accordance with the accompanying drawings. The dimensions, shapes and relative positions of the constituent parts shown in the embodiments should be changed as convenient depending on various conditions and on the structure of the apparatus adapted to the invention, and the invention is not limited to the embodiments described herein.

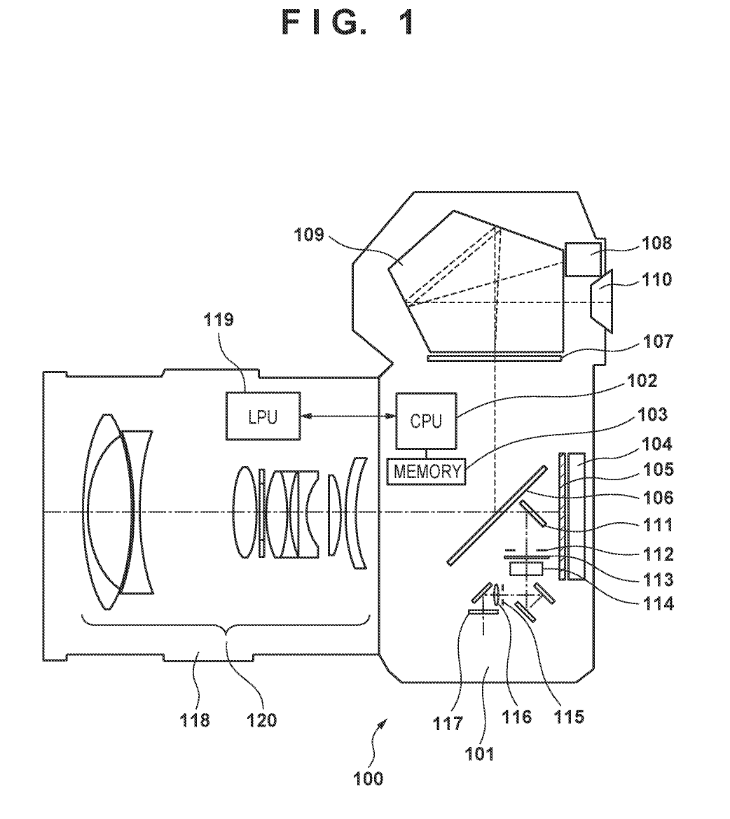

FIG. 1 is a schematic sectional view of a camera as an image capturing apparatus according to an embodiment of the present invention. In FIG. 1, an image capturing apparatus 100 includes a camera main body 101 and a lens unit 118. The camera main body 101 includes a CPU 102, a memory 103, an imaging unit 104, a shutter 105, a half mirror 106, a focusing plate 107, a photometric sensor 108, a pentaprism 109, an optical viewfinder 110, and a sub mirror 111. Further, the camera main body 101 includes a field mask 112, an infrared cut filter 113, a field lens 114, a diaphragm 115, a secondary imaging lens 116, and a focus detection sensor 117. The lens unit 118 includes an LPU 119 and a lens group 120 (imaging optical system).

The CPU 102 performs control in the camera main body 101. The memory 103 is a memory such as a RAM and a ROM connected to the CPU 102, and stores programs executed by the CPU 102 and various data.

When image shooting is not performed, the half mirror 106 reflects a part of the light incident from the lens unit 118 and forms an image on the focusing plate 107. The pentaprism 109 reflects the light passing through the focusing plate 107 to the photometric sensor 108 and the optical viewfinder 110. The photometric sensor 108 includes an image sensor such as a CCD or a CMOS sensor, and performs subject recognition processing such as photometric calculation, face detection computation, tracking computation, and light source detection.

The half mirror 106 transmits a part of the light, and the transmitted light is bent downward at the sub mirror 111 arranged behind the half mirror 106, and the field mask 112, the infrared cut filter 113, the field lens 114, the diaphragm 115, the secondary imaging lens 116 and forms an image on the focus detection sensor 117. Based on the image signal obtained by photoelectric conversion of this image, the focus state of the lens unit 118 is detected.

On the other hand, at the time of image shooting, the half mirror 106 and the sub mirror 111 are retracted from the optical path, and the light entered from the lens unit 118 enters the imaging unit 104 as a subject image via the shutter 105. The shutter 105 can be opened and closed, closed when image shooting is not performed to shield the imaging unit 104 from light, and opened at the time of image shooting to pass light toward the imaging unit 104. The imaging unit 104 includes an image sensor such as a CCD or a CMOS sensor including an infrared cut filter, a low pass filter, and the like, and outputs an image signal corresponding to the amount of incident light.

The LPU 119 performs control to move the lens group 120 in the lens unit 118. For example, upon receiving a defocus amount indicating an amount of defocus from the CPU 102, the LPU 119 moves the lens group 120 to a position where the lens group 120 is in focus (hereinafter referred to as “in-focus position”) based on the defocus amount.

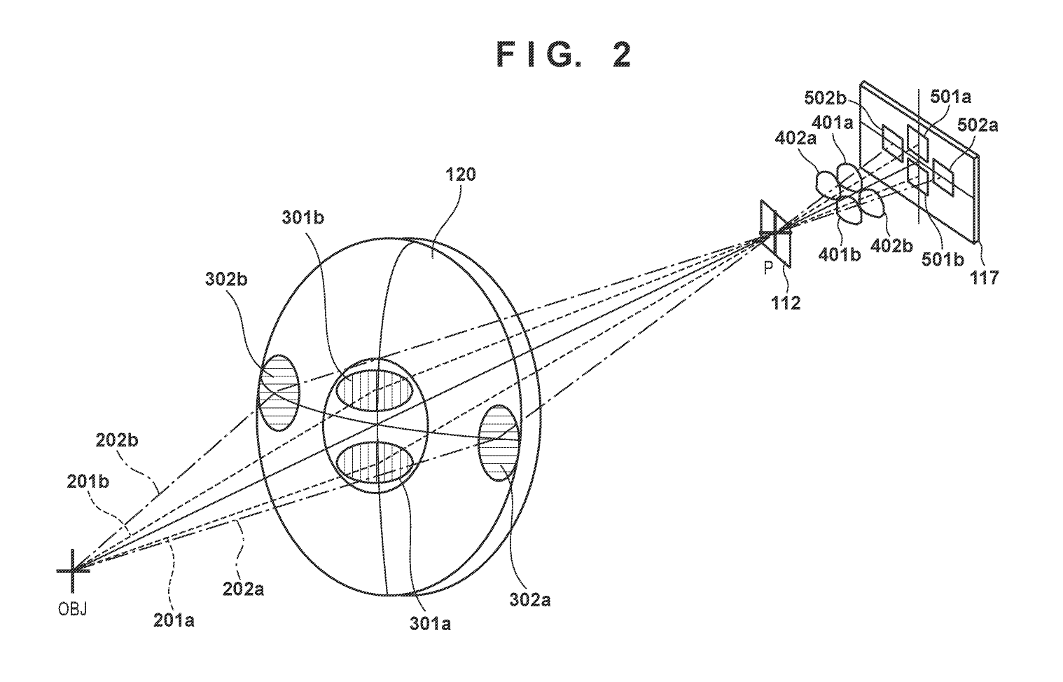

FIG. 2 is a perspective view schematically showing a configuration of a focus detection system. In FIG. 2, the optical path reflected and folded back by the sub mirror 111 or the like is developed and shown. For the sake of explanation, the lens group 120 is represented by a single lens in FIG. 2. Light beams 201a and 201b (incident light) from an object OBJ pass through pupil areas 301a and 301b of the lens group 120 and form images on a focus plane P (primary imaging plane) located in the vicinity of the field mask 112. The light beams 201a and 201b are split up and down (first direction) by secondary imaging lenses 401a and 401b and form images again in imaging areas 501a and 501b of the focus detection sensor 117, and the two upper and lower object images are used for correlation calculation, and a defocus amount is obtained.

Likewise, light beams 202a and 202b (incident light) from the object OBJ pass through pupil areas 302a and 302b located away from the optical axis of the lens group 120 than the pupil areas 301a and 301b, and form images on the focus plane P (primary imaging plane) located in the vicinity of the field mask 112. The light beams 202a and 202b are split in the right and left direction (second direction) by secondary imaging lenses 402a and 402b and form images again in imaging areas 502a and 502b of the focus detection sensor 117, and the left and right two object images are used in correlation calculation, and a defocus amount is obtained.

The imaging areas 502a and 502b correspond to the light beams 202a and 202b having a long base line length and high focus detection accuracy. On the other hand, the imaging areas 501a and 501b correspond to the light beams 201a and 201b having a wide range in which the defocus amount can be detected.

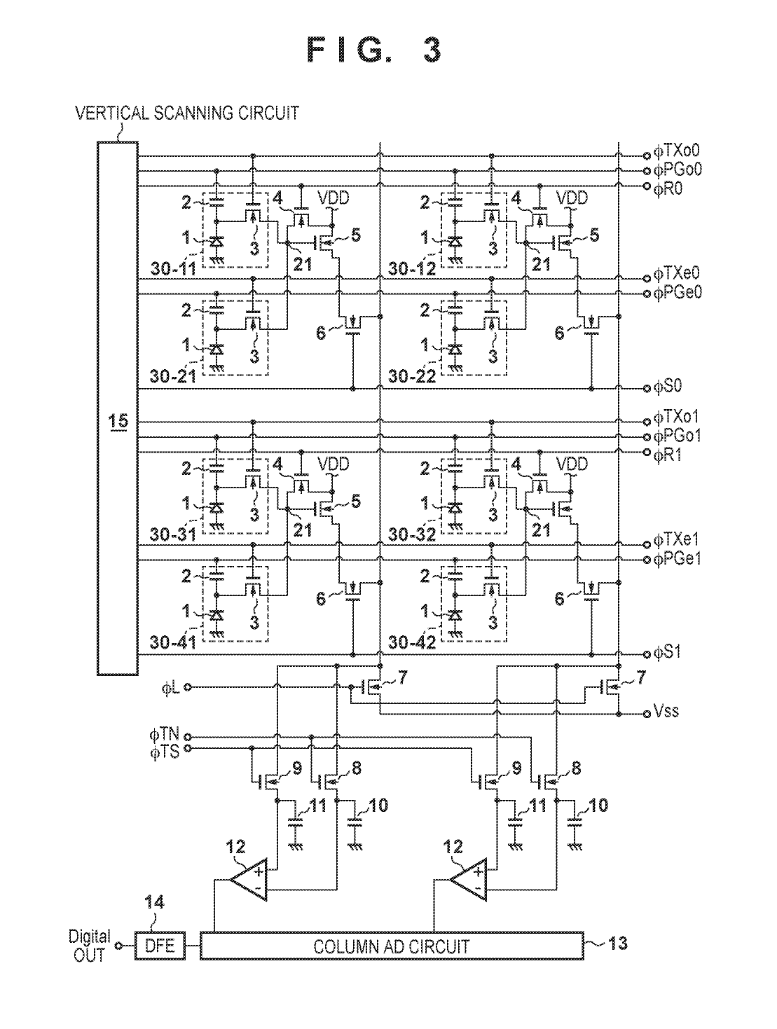

FIG. 3 shows a circuit diagram of the focus detection sensor 117 according to the first embodiment. The focus detection sensor 117 is a two-dimensional CMOS area sensor, and this figure shows a part of the pixels 30-ij (range of 2 rows×4 row pixels). Actually, a large number of pixels having the configuration shown in FIG. 3 are arranged so that high-resolution images can be acquired. Note that i indicates a row number and j indicates a column number.

In FIG. 3, reference numeral 1 denotes a photoelectric conversion portion of a photoelectric conversion element composed of a MOS transistor gate and a depletion layer under the gate; 2, a photogate; 3, a transfer switch MOS transistor; 4, a reset MOS transistor; 21, a floating diffusion (FD) portion; 5, a source follower amplifier MOS transistor; 6, a horizontal selection switch MOS transistor; 7, a load MOS transistor for a source follower; 8, a dark output transfer MOS transistor; 9, a bright output transfer MOS transistor; 10, a dark output capacitor; 11, a bright output capacitor; 12, a differential amplifier; 13, a column AD circuit; 14, a digital front end (DFE) circuit; and 15, a vertical scanning circuit.

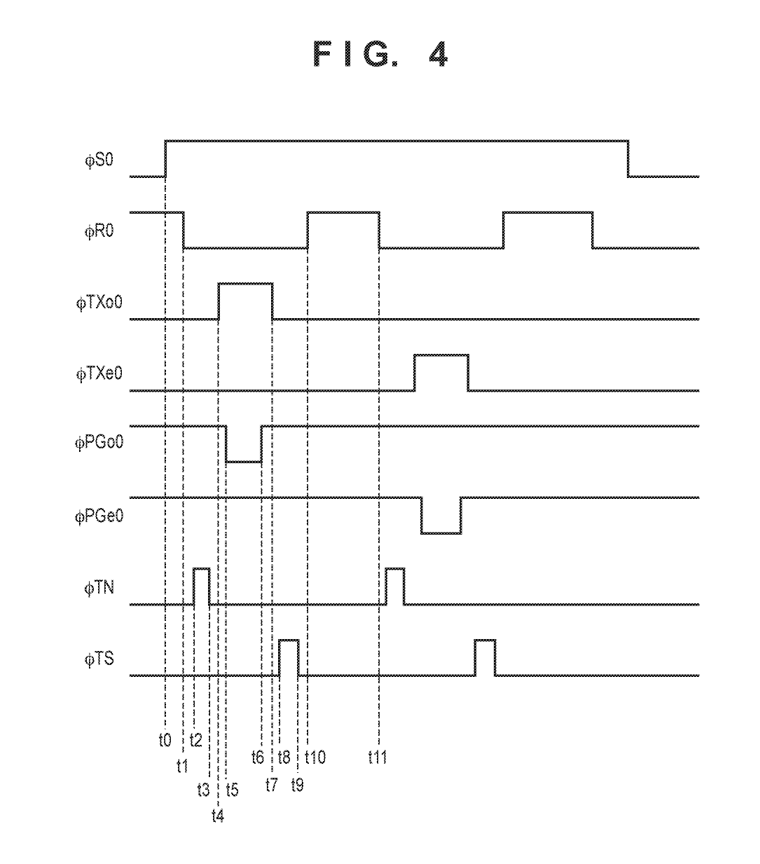

Next, the operation of the focus detection sensor 117 will be described with reference to the timing chart of FIG. 4. First, the vertical scanning circuit 15 resets vertical output lines by setting the control pulse ϕL to a high level. Further, the control pulses ϕR0, ϕPGo0, ϕPGe0 are made high, the reset MOS transistor 4 is turned on, the FD portion 21 is reset, and the charge of the photogate 2 is reset.

At time t0, the control pulse ϕS0 is made high, and the horizontal selection switch MOS transistors 6 of the first and second rows are turned on to select the pixels 30-1j, 30-2j of the first and second rows. Next, at time t1, control pulse ϕR0 is made low, thereby resetting of the FD corresponding portions 21 is stopped, the FD portion 21 are brought into a floating state, and the gate-source paths of the corresponding source follower amplifier MOS transistors 5 are opened. Thereafter, during the period from the time t2 to the time t3, the control pulse ϕTN is made high and the dark voltages of the FD portions 21 are output to the dark output capacitors 10 via the source follower operation.

Next, in order to output charges generated by photoelectric conversion in the pixels 30-1j in the first row, at time t4, the control pulse ϕTXo0 of the first row is made high to make the corresponding transfer switch MOS transistors 3 conductive, and then during the period from time t5 to t6, the control pulse ϕPGo0 is made low. At this time, it is preferable to set the voltage relation such that the potential well spreading under the photogate 2 is raised so that the photocarrier is completely transferred to the FD portion 21. Therefore, if complete transfer is possible, the control pulse ϕTX may not be a pulse but may be a fixed potential.

The electric charges from the photoelectric conversion portions 1 are transferred to the FD portions 21 during the period from time t4 to time t7, so that the potentials of the FD portions 21 change corresponding to the amount of light. At this time, since the source follower amplifier MOS transistors 5 are in a floating state, the control pulse ϕTS is made high during the period from time t8 to time t9 and the potentials of FD portions 21 are readout to the bright output capacitors 11. At this point, since the dark outputs and the light outputs of the pixels 30-1j in the first row are stored in the capacitors 10 and 11, respectively, if differential outputs are taken from a period from time t9 to time t11 by the differential amplifiers 12, it is possible to obtain a signal with a good S/N ratio from which random noise and fixed pattern noise are reduced. The differential outputs are converted into digital data by the column AD circuits 13, and the converted digital data is output to the CPU 102 at a pulse timing controlled by the DFE circuit 14.

During the period from time t8 to time t9, the bright output is outputted to the bright output capacitors 11. Then, the control pulse ϕR0 is made high from time t10 to time t11 to render the corresponding reset MOS transistors 4 conductive and reset the FD portions 21 to the power supply VDD. When the output of the digital data of the first line is completed, the readout operation of the second line is performed. To read out the second line, the drive control pulse ϕTXe0 and the control pulse ϕPGe0 are controlled in the same way, photo charges are stored in the capacitors 10 and 11 by providing high control pulses ϕTN and ϕTS, respectively, thereby obtaining dark output and bright output. With the above-described driving, the pixels 30-1j and 30-2j in the first row and the second row can be read independently.

Thereafter, by reading the 2n+1th rows and the 2n+2th rows (n=1, 2, . . . ) in the same manner as above under control of the vertical scanning circuit 15, it is possible to output signals independently from all the pixels. That is, in the case of n=1, control pulse ϕS1 is made high, then ϕR1 is made low, thereafter the control pulses ϕTN and ϕTXo1 are made high, the control pulse ϕPGo1 is made low and control pulse ϕTS is made high, thereby reading the pixel signals of the pixels 30-3j in the third row. Subsequently, the control pulses ϕTXe1, ϕPGe1 and the control pulse are applied in the same manner as above to read out the pixel signals of the pixels 30-4j in the fourth row.

It should be noted that the vertical scanning circuit 15 is configured to be able to select an arbitrary row in accordance with an instruction from the CPU 102.

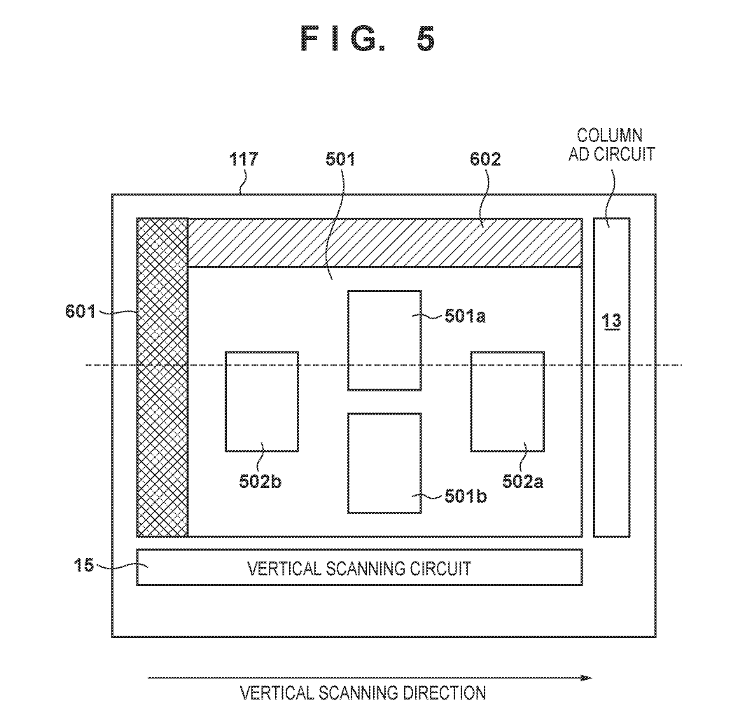

FIG. 5 shows the positional relationship between the imaging area and OB pixels and the vertical scanning circuit 15 in the focus detection sensor 117. The vertical scanning circuit 15 is arranged on the lower side with respect to an effective pixel area 501 including the imaging areas 501a, 501b and the imaging areas 502a, 502b, and selects a row to be read in the direction of the arrow (lateral direction, second direction) to scan. The column AD circuit 13 is arranged in the vertical direction. In the first embodiment, the column AD circuit 13 is arranged on the right side with respect to the effective pixel area 501, however, it may be arranged on the left side. In the peripheral portion of the effective pixel area 501, a vertical OB pixel region (VOB) 601 (first light shielding region) and a horizontal OB pixel region (HOB) 602 (second light shielding region) are arranged. Here, the pixel signal of the imaging area is corrected with VOB shading (vertical direction) which is a mapping of pixel signals from the VOB 601 and HOB shading (horizontal direction) which is a mapping of the pixel signals from the HOB 602. Since pixel signals of the imaging areas 501a and 501b (a pair of first light receiving areas) are for detecting the phase difference in the vertical direction, they are corrected using VOB shading. On the other hand, pixel signals of the imaging areas 502a and 502b (a pair of second light receiving areas) are for detecting the phase difference in the horizontal direction, they are corrected using HOB shading. This is because only the shading component in the direction corresponding to the detection direction of the phase difference (hereinafter, referred to as “correlation direction”) affects the correlation detection result. Although not shown in FIG. 5, when providing an imaging area for detecting the phase difference in the oblique direction, it is desirable to correct both oblique directions using both shadings.

By arranging the vertical scanning circuit 15 as shown in FIG. 5, even if any row is selected, imaging areas having different correlation directions are not simultaneously selected and signals thereof are not outputted. If it is configured so that the vertical scanning circuit is arranged on the right or left side and scanning is performed in the vertical direction, the imaging area 501a and the imaging areas 502a and 502b are simultaneously selected in the row indicated by a dashed line. On the other hand, when a row is selected by the vertical scanning circuit 15, if the correlation direction of the imaging area included in the selected row is the same, it is sufficient to correct only one of the VOB shading and the HOB shading, and it is possible to shorten the time required for AF calculation including correction processing. Although the VOB 601 and the HOB 602 are shielded from light by using a metal such as tungsten, an area which is not the imaging area and other than the VOB 601 and the HOB 602 may be shielded from light. In this case, it is possible to secure a wide area for the VOB 601 and the HOB 602.

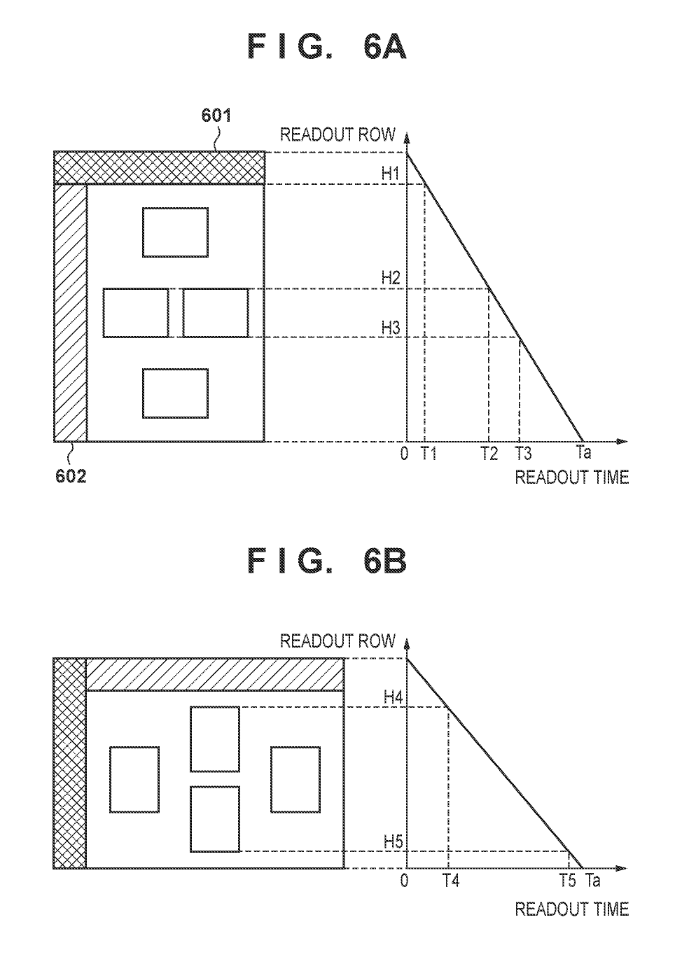

FIGS. 6A and 6B are diagrams for explaining readout time when readout rows are limited. FIG. 6A is a diagram showing readout rows and time in the case where the vertical scanning circuit 15 is arranged as shown in FIG. 5. Although the scanning direction is the horizontal direction, the sensor is rotated by 90 degrees and the scanning direction is shown as the vertical direction for the sake of explanation. On the other hand, FIG. 6B is a view showing readout rows and time in the case where the vertical scanning circuit is arranged on the right or left side and is configured to scan in the vertical direction. In FIGS. 6A and 6B, since the total number of pixels is the same, the time required to read out all the pixels including the OB pixel area is Ta.

Here, it is assumed that a lens darker than the full-open F number of the lens unit 118 is attached. In FIG. 2, when the lens unit 118 with which light can pass through the pupil areas 301a and 301b of the lens group 120 but cannot pass through the pupil areas 302a and 302b is mounted, it is not necessary to read out the pixel signals of the imaging areas 502a and 502b. Namely, the defocus amount may be obtained by performing correlation calculation on the object images in the imaging areas 501a and 501b. Therefore, in the case of FIG. 6A, it is possible to limit the readout rows to the imaging areas 501a and 501b and the VOB 601 necessary for VOB shading. That is, by limiting the readout rows from the row 0 to the row H1 and from the row H2 to the row H3, it is possible to shorten the readout period to T1+(T3−T2).

On the other hand, also in FIG. 6B, the readout rows can be limited from the row H4 to the row H5, and the readout period can be shortened to T5−T4, however, it is necessary to read out more rows than in the case of FIG. 6A, and the effect of shortening the readout period is smaller.

As described above, the vertical scanning circuit 15 of the first embodiment is arranged so that the area where the imaging areas having different correlation directions are simultaneously selected is smaller. Furthermore, in a case where there are a plurality of pairs of imaging areas having different base line lengths in the effective pixel area, the vertical scanning circuit 15 is arranged so that imaging area pairs having short base line length are included in the same row. By configuring the focus detection sensor 117 in this manner, the time required for the AF calculation can be shortened.

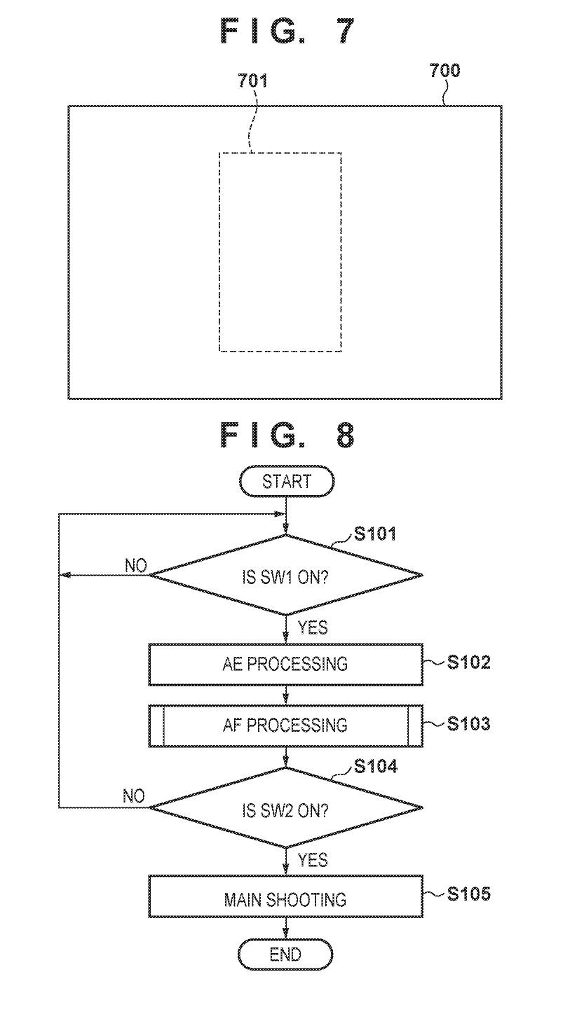

FIG. 7 shows the AF area on a viewfinder screen. An AF area 701 (focus detection area) is set in the center portion of the screen of a viewfinder 700. The AF area 701 corresponds to the imaging areas 501a and 501b having correlation in the vertical direction capable of detecting contrast of horizontal lines. Further, the AF area 701 also corresponds to the imaging areas 502a and 502b having correlation in the lateral direction capable of detecting contrast of vertical lines. Therefore, the phase difference can be detected even if an object has contrast in the vertical or horizontal direction.

FIG. 8 is a flowchart showing a procedure of imaging control processing in the image capturing apparatus 100 shown in FIG. 1. The processing in FIG. 8 is performed by the CPU 102 executing the program stored in the memory 103, and it is assumed that the image capturing apparatus 100 is activated.

In FIG. 8, first, the CPU 102 receives an ON/OFF notification indicating whether or not a half-press (hereinafter referred to as “SW1”) of a shutter switch (not shown) for instructing image shooting has been performed by the user. If SW1 is on (YES in step S101), the CPU 102 controls the photometric sensor 108 to perform AE processing (step S102). As a result, a photometric value including the luminance information of the object under the stationary light is obtained. Also, based on the photometric value obtained here, the exposure control value such as an aperture value and an ISO sensitivity at the time of image shooting, and an accumulation time in the focus detection sensor 117 are determined.

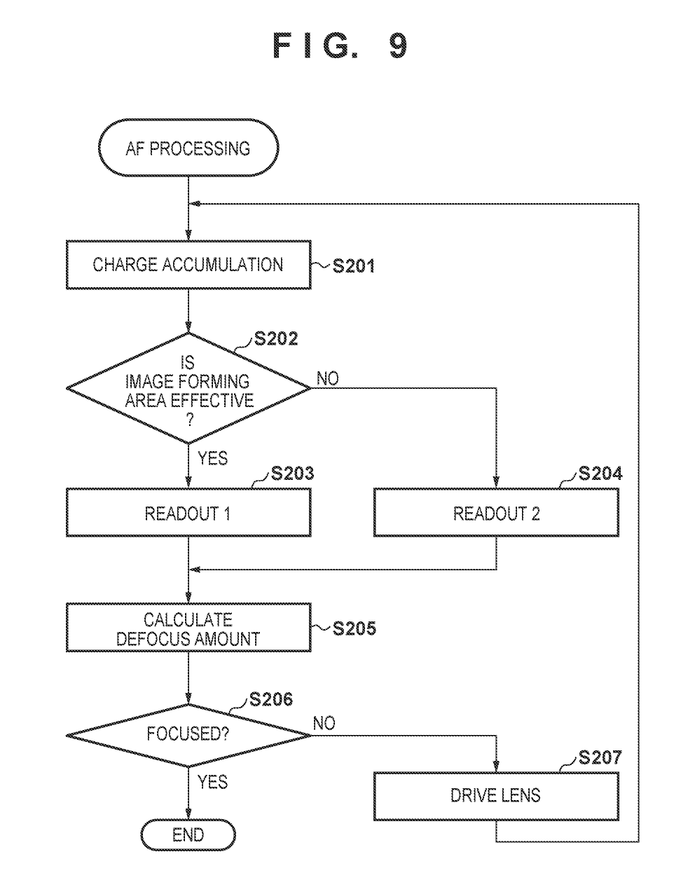

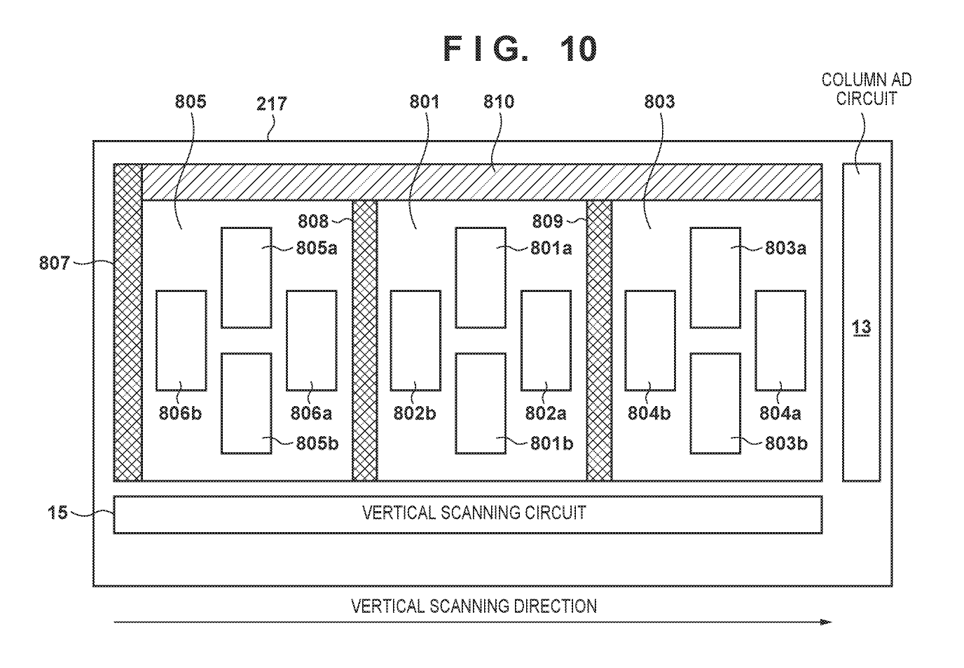

Next, the CPU 102 controls the focus detection sensor 117 to perform a phase difference AF (auto focus) process (step S103). The CPU 102 transmits a lens drive amount based on the defocus amount calculated in the AF process to the LPU 119, and the LPU 119 moves the lens group 120 to the in-focus position based on the received lens drive amount. The process in step S103 will be further described with reference to FIG. 9.

Next, an on/off notification indicating whether or not a full-pressing (hereinafter referred to as “SW2”) of the shutter switch (not shown) has been performed by the user is received, and if SW2 is off (NO in step S104), the CPU 102 returns the process to step S201. On the other hand, if the SW2 is on (YES in step S104), the CPU 102 performs the main shooting (step S105), and then ends the present processing.

FIG. 9 is a flowchart showing the procedure of the AF process in step S103 of FIG. 8. First, in step S201, the CPU 102 executes an accumulation operation of the focus detection sensor 117 with the accumulation time determined in step S102 based on the photometric value including the luminance information of the object.

In step S202, the CPU 102 determines whether the imaging areas 502a and 502b are valid or invalid. The CPU 102 communicates with the LPU 119 of the lens unit 118 attached to the image capturing apparatus 100 to determine whether or not light beams can pass through the pupil areas 302a and 302b based on the full-open F number or pupil information of the lens. If the light beams can pass through the pupil areas 302a and 302b, it is determined that the imaging areas 502a and 502b are valid, and the process proceeds to step S203. On the other hand, if the light beams cannot pass through the pupil areas 302a and 302b, it is determined that the imaging areas 502a and 502b are invalid and the process proceeds to step S204.

In step S203, since the imaging areas 502a and 502b are determined to be valid in step S202, the CPU 102 instructs the focus detection sensor 117 to output signals from all pixels including pixels in the OB pixel area, and a readout operation (Readout 1) is performed.

On the other hand, in step S204, since the imaging areas 502a and 502b are determined to be invalid in step S202, the CPU 102 instructs the focus detection sensor 117 to output limited signals from the imaging areas 501a and 501b, and a readout operation (Readout 2) is performed. The limited output is as described in FIG. 6A.

In step S205, the CPU 102 calculates a defocus amount from the pixel signals for each imaging area obtained in step S203 or step S204. Here, signal images are obtained from the pixel output on the same row of the pair of imaging areas. Then, from the phase difference of the signal images, a focus state (defocus amount) of the imaging lens is detected. Calculation results of the defocus amounts of respective rows are averaged, weighted averaged, or the like, and the obtained value is taken as the final result of each imaging area pair. Further, in a case where the defocus amounts are obtained for the imaging areas 501a and 501b and imaging areas 502a and 502b by the Readout 1, one of the defocus amounts is selected. Although there is no particular limitation on the selection method, the defocus amount which is considered to have high reliability of the defocus amount, such that correlation of the waveform of the signal images is high, contrast of the signal images is high, and so forth, may be selected. Alternatively, the two defocus amounts may be averaged or weighted averaged.

In step S206, if the defocus amount calculated in step S205 is within a desired range, for example, within ¼Fδ (F: aperture value of the lens, δ: constant (20 μm)), the CPU 102 determines that the image is in focus. Specifically, if the aperture value F of the lens is 2.0, in the case where the defocus amount is 10 μm or less, it is determined that the image is in focus and the AF process is ended.

On the other hand, if the defocus amount calculated in step S205 is larger than ¼Fδ, the CPU 102 transmits the lens drive amount corresponding to the defocus amount obtained in step S205 to the lens unit 118 in step S207. Then, the CPU 102 returns the process to step S201 and repeats the above-described operation until it is determined that the focused state is achieved.

According to the first embodiment as described above, the vertical scanning circuit is disposed in such a direction that, in the focus detection sensor, focusing areas having different correlation directions are not simultaneously selected and read out. Furthermore, based on the information from the lens, it is determined whether or not the pairs of imaging areas in the focus detection sensor are valid or invalid. Then, by selecting the readout rows by limiting to the effective imaging areas by the vertical scanning circuit and outputting signals only from the pixels in the selected rows, the time required for the AF control can be shortened.

### Second Embodiment

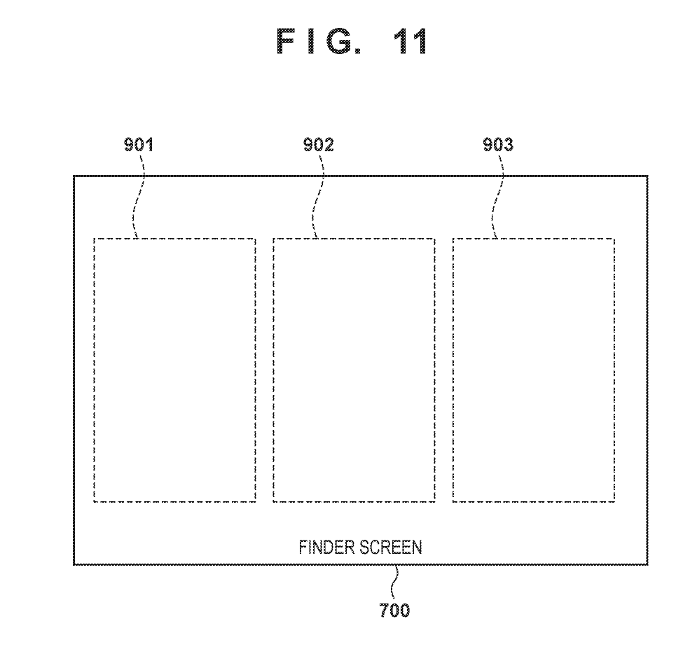

Next, a second embodiment of the present invention will be described in detail with reference to the accompanying drawings. FIG. 10 shows the positional relationship between an imaging area, an OB pixel, and a vertical scanning circuit 15 in the focus detection sensor 217 according to the second embodiment. The focus detection sensor 217 is used in place of the focus detection sensor 117, and the configuration of the imaging device other than this is the same as that of the first embodiment, so its description will be omitted.

The focus detection sensor 117 according to the first embodiment has two pairs of imaging areas, and the AF area 701 is located at the center of the screen of the viewfinder 700. By contrast, the focus detection sensor 217 according to the second embodiment has six pairs of imaging areas and enlarges the AF area in the left and right region of the screen in addition to the central portion of the screen.

At the central portion of the focus detection sensor 217, two pairs of imaging areas, i.e., imaging areas 801a and 801b with correlation direction in the horizontal direction and imaging areas 802a and 802b with the correlation direction in the vertical direction, are arranged. The baseline lengths of the imaging areas 801a and 801b and the imaging areas 802a and 802b have the same relationship as the focus detection sensor 117, and the baseline length of the imaging areas 802a and 802b is longer.

In the left and right portions of the focus detection sensor 217, two imaging areas are arranged similarly to the central portion. In the right portion of the focus detection sensor 217, two pairs of imaging areas, i.e., imaging areas 803a and 803b having the correlation direction in the vertical direction and imaging areas 804a and 804b having the correlation direction in the horizontal direction, are arranged. Further, in the left portion of the focus detection sensor 217, two pairs of imaging areas, i.e., imaging areas 805a and 805b having the correlation direction in the vertical direction and imaging areas 806a and 806b having the correlation direction in the horizontal direction, are arranged.

The vertical scanning circuit 15 is disposed on the lower side with respect to effective pixel regions 801, 803, and 805, and scans in the direction of an arrow (lateral direction). The column AD circuits 13 are arranged in the vertical direction (direction orthogonal to the arrow). Note that in FIG. 10, the column AD circuits 13 are disposed on the right side with respect to the effective pixel regions 801, 803, and 805, however it may be arranged on the left side. In the peripheral parts of the effective pixel regions 801, 803, and 805, OB pixel regions VOB 807 and HOB 810 are arranged. Further, an OB pixel region VOB 808 is provided between the center effective pixel region 801 and the left effective pixel region 805, and an OB pixel region VOB 809 is provided between the center effective pixel region 801 and the right effective pixel region 803.

Here, the pixel signals of the imaging area are corrected using VOB shading (row direction) which is mappings of the respective pixel signals of the VOB 807, VOB 808, and VOB 809, and HOB shading (column direction) which is a mapping of the pixel signals of HOB 810. Based on the shading of the VOB 807, pixel signals of the imaging areas 805a and 805b are corrected. Similarly, pixel signals of the imaging areas 801a and 801b are corrected based on the shading of the VOB 808. Likewise, pixel signals of the imaging areas 803a and 803b are corrected on the basis of the shading of the VOB 809, and based on the shading of the HOB 810, pixel signals of the imaging areas 806a and 806b, the imaging areas 802a and 802b, and the imaging areas 804a and 804b are corrected.

By disposing the vertical scanning circuit 15 as shown in FIG. 10, even if any row is selected, imaging areas having different correlation directions are not simultaneously selected and signals thereof are not outputted. Further, by selecting rows in the middle of the effective pixel regions by the vertical scanning circuit 15, it is possible to read out limited rows in the central imaging area, the right imaging area, and the left imaging area, respectively.

FIG. 11 shows the relationship of the AF areas (focus detection areas) in the viewfinder screen according to the second embodiment. An AF area 902 is set in the center of the screen of the viewfinder 700, an AF area 903 is set on the right side thereof, and an AF area 901 is set on the left side thereof. The AF area 902 corresponds to the imaging areas 801a and 801b and the imaging areas 802a and 802b. The AF area 903 corresponds to the imaging areas 803a and 803b and the imaging areas 804a and 804b. The AF area 901 corresponds to the imaging areas 805a and 805b and the imaging areas 806a and 806b.

A user can arbitrarily select any one of the AF areas 901 to 903 as the AF target by operating an AF selection switch (not shown) of the image capturing apparatus 100.

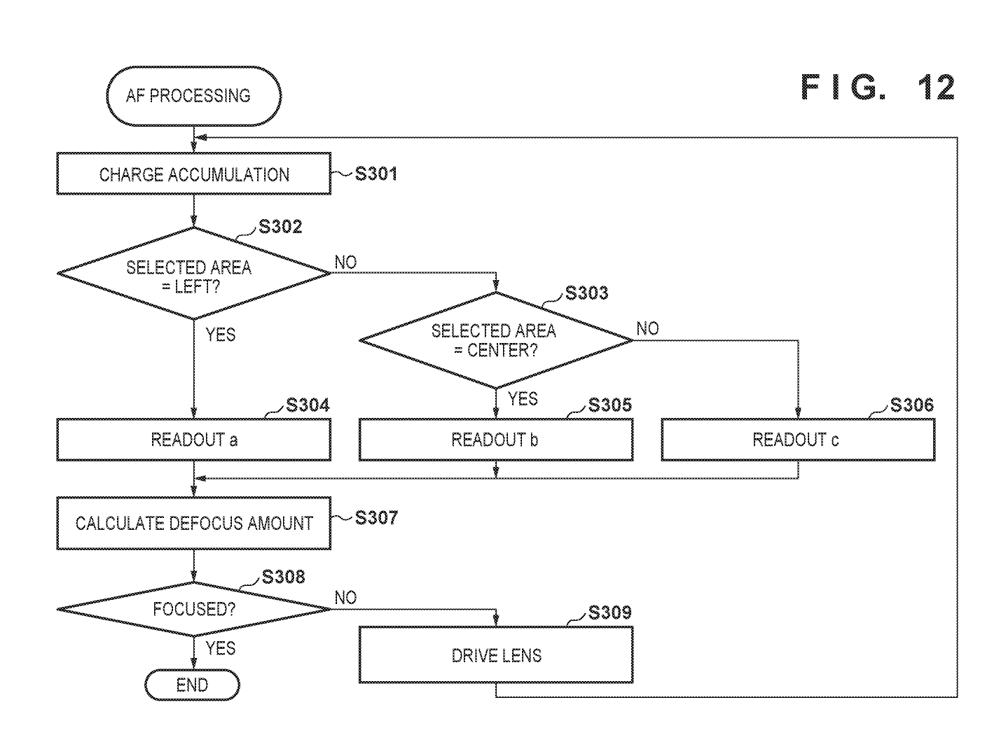

FIG. 12 is a flowchart showing the procedure of the AF process in the second embodiment. Since the imaging control processing in the second embodiment is the same as the flowchart shown in FIG. 10, the description will be omitted.

In step S301, the CPU 102 executes the accumulation operation of the focus detection sensor 217 with the accumulation time determined based on the photometric value including the object luminance information determined in step S102.

In steps S302 and S303, the CPU 102 determines the selected area out of the AF areas 901 to 903 by the AF selection switch (not shown). In step S302, the CPU 102 receives the state of the AF selection switch operated by the user, and determines whether or not the AF area 901 is selected. If the AF area 901 is selected, the process proceeds to step S304. On the other hand, if the area other than the AF area 901 is selected, the process proceeds to step S303.

In step S303, the CPU 102 receives the state of the AF selection switch operated by the user, and determines whether or not the AF area 902 is selected. If the AF area 902 is selected, the process proceeds to step S305. On the other hand, if the AF area 902 is not selected, the process proceeds to step S306.

In step S304, the CPU 102 instructs the focus detection sensor 217 to perform limited output of signals from the imaging areas 805a and 805b, the imaging areas 806a and 806b, and the VOB 807, and performs a readout operation (Readout a).

In step S305, the CPU 102 instructs the focus detection sensor 217 to perform limited output of signals from the imaging areas 801a and 801b, the imaging areas 802a and 802b, and the VOB 808, and performs a readout operation (Readout b).

In step S306, the CPU 102 instructs the focus detection sensor 217 to perform limited output of signals from the imaging areas 803a and 803b, the imaging areas 804a and 804b, and the VOB 809, and performs a readout operation (Readout c).

In step S307, the CPU 102 calculates a defocus amount from the pixel signals of respective imaging areas obtained in any one of steps S304 to S306. Then, one of the obtained defocus amounts for the respective imaging area is selected. Although there is no particular limitation on the selection method, the defocus amount which is considered to have high reliability of the defocus amount, such that correlation of the waveform of the signal images is high, contrast of the signal images is high, and so forth, may be selected. Alternatively, the two defocus amounts may be averaged or weighted averaged.

In step S308, if the defocus amount calculated in step S307 is within a desired range, for example, within ¼Fδ (F: aperture value of the lens, δ: constant (20 μm)), the CPU 102 determines that the image is in focus. Specifically, if the aperture value F of the lens is 2.0, in the case where the defocus amount is 10 μm or less, it is determined that the image is in focus and the AF process is ended.

On the other hand, if the defocus amount calculated in step S307 is larger than ¼Fδ, the CPU 102 transmits the lens drive amount corresponding to the defocus amount obtained in step S307 to the lens unit 118 in step S309. Then, the CPU 102 returns the process to step S301 and repeats the above-described operation until it is determined that the focused state is achieved.

According to the second embodiment as described above, the vertical scanning circuit is disposed in such a direction that a plurality of AF areas are not simultaneously selected and read out. Furthermore, based on the selection information of the AF area, validity of each of a plurality of imaging areas in the focus detection sensor is determined. Then, by limiting to valid imaging areas by the vertical scanning circuit and outputting signals only from the pixels in the valid imaging areas, the time required for the AF control can be shortened.

In the second embodiment as well, the vertical scanning circuit is arranged in such a direction that imaging areas having different correlation directions are not simultaneously selected and read out in the focus detection sensor. Therefore, after limiting the AF area, the imaging area to be read out may be limited based on the lens information as described in the first embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-058657, filed on Mar. 26, 2018 which is hereby incorporated by reference herein in its entirety.

What is claimed is:

1. A focus detection apparatus comprising:
an image sensor having
a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, and
a scanning unit that selects rows of the pixel area from which signals are read out,
wherein the first light receiving areas and the second light receiving areas are arranged so as not to be simultaneously included in the rows selected by the scanning unit.

2. The focus detection apparatus according to claim 1 further comprising a dividing unit that divides incoming light beams that enter via an imaging optical system into the pair of light beams divided in the first direction and the pair of light beams divided in the second direction.

3. The focus detection apparatus according to claim 1 further comprising a focus detection unit that detects a focus state based on at least one of a phase difference between a pair of first signals read out from the pair of first light receiving areas and a phase difference between a pair of second signals read out from the pair of second light receiving areas.

4. The focus detection apparatus according to claim 2, wherein a plurality of focus detection regions are set in the second direction in the image sensor, and
the dividing unit divides incoming light beams that enter each of the plurality of focus detection regions via the imaging optical system into the pair of light beams divided in the first direction and the pair of light beams divided in the second direction.

5. The focus detection apparatus according to claim 4 further comprising a selector that selects one of the plurality of focus detection regions,
wherein the scanning unit selects the rows in the selected focus detection regions.

6. The focus detection apparatus according to claim 1, wherein a base line length of the pair of light beams divided into the second direction is longer that a base line length of the pair of light beams divided into the first direction, and the scanning unit selects the rows of pixels which are arranged in the first direction.

7. The focus detection apparatus according to claim 1 further comprising an acquisition unit that acquires information on an imaging optical system,
wherein the pair of first light receiving areas receive the pair of light beams obtained by dividing incoming light beams that enter via a first pupil region of the imaging optical system in the first direction, and the pair of second light receiving areas receive the pair of light beams obtained by dividing incoming light beams that enter via a second pupil area located farther from an optical axis of the imaging optical system than the first pupil region in the second direction, and
wherein in a case where it is determined based on the acquired information that light beams do not enter via the second pupil area, the scanning unit does not read out a signal from the second light receiving areas.

8. The focus detection apparatus according to claim 3, wherein the image sensor further has a first light-shielded region and a second light-shielded region provided along periphery of the pixel region in the first direction and in the second direction, respectively,
the scanning unit selects the rows so as to read out signals from the first light-shielded region in order to correct the pair of first signals and to read out signals from the second light-shielded region in order to correct the pair of second signals, and
the focus detection unit corrects the pair of first signals using the signals read out from the first light-shielded region, corrects the pair of second signals using the signals read out from the second light-shielded region, and obtains the phase difference using the corrected pair of first signals and the corrected pair of second signals.

9. The focus detection apparatus according to claim 8, wherein the scanning unit selects the rows so as not to read out signals from the second light-shielded region in a case where signals are not read out from rows of the second light receiving areas.

10. The focus detection apparatus according to claim 1 further comprising analog-to-digital converters provided in a direction orthogonal to the rows.

11. A focus detection apparatus comprising:
a dividing unit that divides incoming light beams that enter via an imaging optical system into a plurality of different directions;
an image sensor having
a pixel region, having a plurality of pixels, which includes a plurality of pairs of light receiving areas that receive the light beams divided by the dividing unit, and
a scanning unit that selects rows of the pixel area from which signals are read out; and
a focus detection unit that detects a focus state based on phase differences between a plurality of pairs of signals read out from the plurality of pairs of light receiving areas, respectively,
wherein the dividing unit divides the light beams so that the plurality of pairs of light receiving areas whose detection directions of the phase difference are different are not simultaneously included in the rows selected by the scanning unit.

12. The focus detection apparatus according to claim 11, wherein the plurality of pairs of light receiving areas include a pair of first light receiving areas having a short base line length and a pair of second light receiving areas having a base line length longer than the pair of first light receiving areas, and the pair of first light receiving areas are arranged in a row direction.

13. A focus detection apparatus comprising:
an image sensor having
a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction,
a first light-shielded region and a second light-shielded region provided along periphery of the pixel region in the first direction and in the second direction, respectively, and
a scanning unit that selects rows of the pixel area from which signals are read out,
wherein the scanning unit selects the rows so as to read out signals from the first light-shielded region in order to correct a pair of first signals read out from the pair of first light receiving areas and to read out signals from the second light-shielded region in order to correct a pair of second signals read out from the pair of second light receiving areas.

14. The focus detection apparatus according to claim 13 further comprising a focus detection unit that detects a focus state based on at least one of a phase difference between the pair of first signal and a phase difference between the pair of second signals,
wherein the focus detection unit corrects the pair of first signals using the signals read out from the first light-shielded region, corrects a pair of second signals using the signals read out from the second light-shielded region, and calculates the phase difference between the corrected signals.

15. An image capturing apparatus comprising:
an image sensing device that performs photoelectric conversion on light beams incoming via an imaging optical system and outputs an image signal;
the focus detection apparatus comprising
an image sensor having
a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction, and
a scanning unit that selects rows of the pixel area from which signals are read out; and
a controller that controls the imaging optical system based on a focus state detected by the focus detection apparatus,
wherein the first light receiving areas and the second light receiving areas are arranged so as not to be simultaneously included in the rows selected by the scanning unit.

16. An image capturing apparatus comprising:
an image sensor that performs photoelectric conversion on light beams incoming via an imaging optical system and outputs an image signal;
the focus detection apparatus comprising
a dividing unit that divides incoming light beams that enter via an imaging optical system into a plurality of different directions;
an image sensor having
a pixel region, having a plurality of pixels, which includes a plurality of pairs of light receiving areas that receive the light beams divided by the dividing unit, and
a scanning unit that selects rows of the pixel area from which signals are read out; and
a focus detection unit that detects a focus state based on phase differences between a plurality of pairs of signals read out from the plurality of pairs of light receiving areas, respectively; and
a controller that controls the imaging optical system based on a focus state detected by the focus detection apparatus,
wherein the dividing unit divides the light beams so that the plurality of pairs of light receiving areas whose detection directions of the phase difference are different are not simultaneously included in the rows selected by the scanning unit.

17. An image capturing apparatus comprising:
an image sensor that performs photoelectric conversion on light beams incoming via an imaging optical system and outputs an image signal;
the focus detection apparatus comprising
an image sensor having
a pixel region, having a plurality of pixels, which includes a pair of first light receiving areas that receive a pair of light beams which have undergone pupil division in a first direction, and a pair of second light receiving areas that receive a pair of light beams which have undergone pupil division in a second direction different from the first direction,
a first light-shielded region and a second light-shielded region provided along periphery of the pixel region in the first direction and in the second direction, respectively, and
a scanning unit that selects rows of the pixel area from which signals are read out; and
a controller that controls the imaging optical system based on a focus state detected by the focus detection apparatus,
wherein the scanning unit selects the rows so as to read out signals from the first light-shielded region in order to correct a pair of first signals read out from the pair of first light receiving areas and to read out signals from the second light-shielded region in order to correct a pair of second signals read out from the pair of second light receiving areas.
